(19) United States
(12) Patent Application Publication
(10) Pub. No.: US 2014/0076618 A1
(43) Pub. Date: Mar. 20, 2014

(54) METHOD OF FORMING GOLD THIN FILM AND PRINTED CIRCUIT BOARD

(71) Applicants: SAMSUNG ELECTRO-MECHANICS CO., LTD., Suwon-si (KR); RESEARCH & BUSINESS FOUNDATION SUNGK, Suwon-si (KR)

(72) Inventors: Seong Min CHO, Suwon-si (KR); Chan Hwa CHUNG, Suwon-si (KR); Chang Yong AN, Suwon-si (KR); Chang Sup RYU, Suwon-si (KR); Hyo Seung NAM, Suwon-si (KR)

(73) Assignees: RESEARCH & BUSINESS FOUNDATION SUNGKYUNKWAN UNIVERSITY, Suwon-si (KR); Samsung Electro-Mechanics Co., Ltd., Suwon-si (KR)

(21) Appl. No.: 13/692,643

(22) Filed: Dec. 3, 2012

(30) Foreign Application Priority Data
Sep. 14, 2012 (KR) 10-2012-0102287

(51) Int. Cl. H05K 3/18; H05K 1/09

(52) U.S. Cl. CPC H05K 3/188; H05K 1/09
USPC 174/257; 205/85

(57) ABSTRACT

There is provided a method of forming a gold thin film, the method including: forming a nickel plating layer on a surface of an object through electroless nickel (Ni) plating; forming a palladium-copper mixture plating layer on the nickel plating layer through electroless plating using a palladium-copper (Pd—Cu) mixture; and forming a first gold thin film by immersing the palladium-copper mixture plating layer in a gold (Au) galvanic electrolytic liquid to replace a portion of copper (Cu) particles in the palladium-copper mixture plating layer with gold particles through a replacement reaction.

### CROSS-REFERENCE TO RELATED APPLICATIONS

This application claims the priority of Korean Patent Application No. 10-2012-0102287 filed on Sep. 14, 2012, in the Korean Intellectual Property Office, the disclosure of which is incorporated herein by reference.

### BACKGROUND OF THE INVENTION

1. Field of the Invention

The present invention relates to a printed circuit board and a method of forming a gold (Au) thin film by surface-treating the printed circuit board.

2. Description of the Related Art

Aboard on which a specific circuit pattern is printed is used in various electronic products such as computers, semiconductors, displays, communication devices, and the like.

As for a general printed circuit board, after a copper (Cu) circuit pattern is formed on a copper clad laminate (CCL), a nickel plating layer and a gold plating layer may be sequentially laminated on the circuit pattern, and then, a surface treatment may be finally performed.

The nickel plating layer is used as a plating underlayer, and may serve to prevent mutual diffusion between the copper circuit pattern and the gold plating layer.

The gold plating layer serves to reduce electric resistance at a contact point between a printed circuit board and an electronic component and improve binding therebetween.

This gold plating layer may be generally formed through electroless nickel/immersion gold (ENIG) surface plating. The gold thin film formed during this process may be provided with a thickness of about 1 μm, in which a large amount of gold may be used.

For this reason, in order to reduce the amount of gold required, electroless nickel/electroless palladium/immersion gold (ENEPIG) plating, in which palladium plating is further carried out, has been developed and applied to mass production processes.

However, the ENEPIG method causes deterioration in the adhesive properties of the palladium thin film and the gold film, and thus has a limitation that the gold thin film needs to have a thickness of at least about 0.1 μm for wire bonding.

### SUMMARY OF THE INVENTION

An aspect of the present invention provides a method of forming a gold thin film capable of reducing manufacturing costs, in which the thickness of the gold thin film formed at the time of substrate surface treatment is 1 μm or less, to thereby reduce the amount of gold required, and a printed circuit board using the same.

According to an aspect of the present invention, there is provided a method of forming a gold thin film, the method including: forming a nickel plating layer on a surface of an object through electroless nickel (Ni) plating; forming a palladium-copper mixture plating layer on the nickel plating layer through electroless plating using a palladium-copper (Pd—Cu) mixture; and forming a first gold thin film by immersing the palladium-copper mixture plating layer in a gold (Au) galvanic electrolytic liquid to replace a portion of copper (Cu) particles in the palladium-copper mixture plating layer with gold particles through a replacement reaction.

The method may further include, before the forming of the palladium-copper mixture plating layer, forming a palladium plating layer on the nickel plating layer through electroless palladium (Pd) plating.

The method may further include, after the forming of the first gold thin film, forming a second gold thin film on the first gold thin film through electroless gold (Au) plating.

The palladium-copper mixture may contain a palladium salt, a copper salt, a complexing agent, and a reducing agent.

The palladium salt may be one selected from the group consisting of palladium chloride, palladium sulfate, and dichlorotetraamine palladium.

The copper salt may be one selected from the group consisting of copper sulfate (CuSO₄) and copper chloride (CuCl₂).

The reducing agent may be one selected from the group consisting of formaldehyde, hydrazine, and dimethylamineborane.

According to another aspect of the present invention, there is provided a printed circuit board, including: a substrate; a copper circuit pattern formed on a surface of the substrate; a nickel plating layer formed on the copper circuit pattern; a palladium-copper mixture plating layer formed on the nickel plating layer; and a first gold thin film formed on the palladium-copper mixture plating layer.

The nickel plating layer and the palladium-copper mixture plating layer may include a palladium plating layer interposed therebetween.

The first gold thin film may include a second gold thin film formed thereon.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view schematically showing a surface treatment structure of a printed circuit board according to an embodiment of the present invention;

FIG. 2 is a cross-sectional view schematically showing a surface treatment structure of a printed circuit board according to another embodiment of the present invention;

FIG. 3 is a process flow chart showing a surface treatment process of the printed circuit board according to an embodiment of the present invention;

FIG. 4 is a schematic diagram showing the Galvanic Replacement Reaction employed according to an embodiment of the present invention;

FIG. 5A is an Focused Ion Beam-Scanning Electron Microscope (FIB-SEM) image of a surface of the printed circuit board according to an embodiment of the present invention before the Galvanic Replacement Reaction;

FIG. 5B is an FIB SEM image of a surface of the printed circuit board according to an embodiment of the present invention after the Galvanic Replacement Reaction;

FIG. 6 is a graph showing an X-ray photoelectron spectroscopy result of a surface of the printed circuit board according to an embodiment of the present invention;

FIG. 7A is an FIB SEM image of a surface of the printed circuit board according to an embodiment of the present invention; and

FIG. 7B is an FIB SEM image of a surface of the printed circuit board according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

In the printed circuit board according to an embodiment of the present embodiment, electrical signals between electronic components mounted on the board flow between one another by using a copper circuit pattern.

Here, gold conductive lines and semiconductors may be connected to each other on an upper surface of the printed circuit board, and solder balls serving as a lead may be mounted on a lower surface of the printed circuit board.

This printed circuit board may be formed with a single layer structure or a multilayer structure of two or more layers, as necessary.

Hereinafter, a surface treatment structure of this printed circuit board will be described in detail.

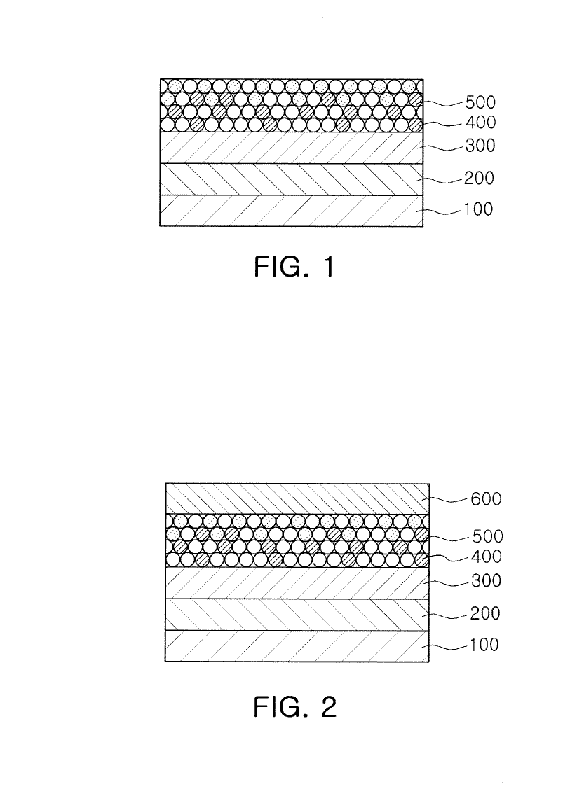

Referring to FIG. 1, a surface of the printed circuit board according to the present embodiment may include a circuit pattern 100, a nickel (Ni) plating layer 200 formed on the circuit pattern 100, a palladium-copper (Pd—Cu) mixture plating layer 400 formed on the nickel plating layer 200, and a first gold (Au) thin film 500 formed on the palladium-copper mixture plating layer 400.

The circuit pattern 100 may be formed of copper (Cu) having excellent electric conductivity.

Circuit patterns 100 may be formed on both surfaces of the printed circuit board. A via electrode (not shown) may be formed to vertically penetrate the printed circuit board so that the via electrode may electrically connect the circuit patterns 100 formed on both surfaces of the printed circuit board.

Here, a palladium (Pd) plating layer 300 may be interposed between the nickel plating layer 200 and the palladium-copper mixture plating layer 400.

The first gold thin film 500 may serve as a bonding part for being electrically connected to wires in the printed circuit board, and may be formed by replacing a portion of copper particles in a palladium-copper mixture with gold through the galvanic replacement reaction of the palladium-copper mixture plating layer 400.

Here, referring to FIG. 2, a second gold thin film 600 with a predetermined thickness may be further formed on the first gold thin film 500, as necessary.

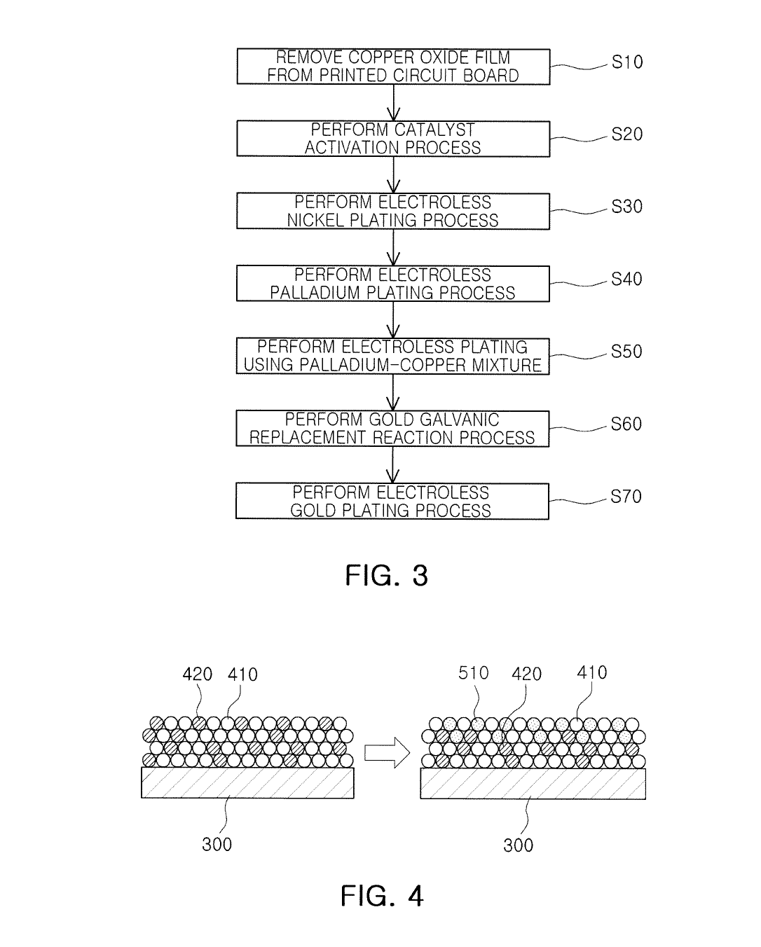

Hereinafter, referring to FIG. 3, a surface treatment process of the printed circuit board according to an embodiment of the present invention will be described in detail.

First, a copper oxide film is removed from the surface of the printed circuit board on which a circuit pattern of copper is formed, and the surface of the printed circuit board is washed (S10).

For the removing of the copper oxide film and the washing of the printed circuit board, the printed circuit board is immersed in an acid solution, containing sulfuric acid, at room temperature to remove the copper oxide film, and is then washed with deionized (DI) water.

Then, a catalyst activation process of the circuit pattern 100, from which the copper oxide film has been removed, is performed in order to form a nickel plating layer 200 (S20).

The catalyst activation process may be performed on the circuit pattern 100 from which the copper oxide film has been removed by using a tin and palladium colloidal solution.

Here, a colloidal solution containing platinum, gold, or silver, precious metals, may be used instead of palladium.

For example, the circuit pattern 100 may be immersed in a solution containing hydrochloric acid (HCl) and tin chloride (SnCl₂) in DI water at room temperature, and then immersed in a solution containing hydrochloric acid (HCl) and palladium chloride (PdCl₂) in DI water at room temperature, to allow palladium to be precipitated.

Then, the nickel plating layer 200 with a predetermined thickness is formed on the circuit pattern 100 through electroless nickel plating on the surface of the substrate (S30).

As for the electroless nickel plating, an electroless plating liquid may be prepared from, for example, nickel chloride (NiCl₂), sodium hypophosphite (NaH₂PO₂), sodium citrate (Na₃C₆H₅O₇), and sodium acetate (NaC₂H₃O₂), and may be then used to form a nickel thin film on the foregoing catalyst-activated circuit pattern 100.

Here, nickel sulfate may be used instead of nickel chloride as a nickel salt, but the present invention is not limited thereto.

In addition, as necessary, the palladium plating layer 300 having a predetermined thickness may be further formed on the nickel plating layer 200 through electroless palladium plating (S40).

As for the electroless palladium plating, an electroless plating liquid may be prepared from, for example, palladium chloride (PdCl₂), ammonia water (NH₄OH), ethylenediaminetetraacetic acid (EDTA), hydrochloric acid (HCl), and hydrazine (N₂H₄), and may be then used to form a palladium thin film on the nickel plating layer 200.

Here, palladium sulfate (PdSO₄) or dichlorotetraamine palladium (Pd(NH₃)₄Cl₂) may be used instead of palladium chloride, as a palladium salt, but the present invention is not limited thereto.

Then, the palladium-copper mixture plating layer 400 with a predetermined thickness is formed on the nickel plating layer 200 or the palladium plating layer 300 formed on the nickel plating layer 200, through electroless plating using a palladium-copper mixture (S50).

The palladium-copper mixture plating layer 400 is used as a sacrificial metal for forming a gold thin film by the following procedure, a galvanic replacement procedure.

Here, the palladium-copper mixture may contain a palladium salt, a copper salt, a complexing agent, and a reducing agent.

Examples of the palladium salt may include one selected from the group consisting of palladium chloride, palladium sulfate, and dichlorotetraamine palladium.

Examples of the copper salt may include one selected from the group consisting of copper sulfate (CuSO₄) and copper chloride (CuCl₂).

Examples of the reducing agent may include one selected from the group consisting of formaldehyde, hydrazine, and dimethylamineborane.

An electroless plating liquid for the electroless plating using a palladium-copper mixture may be prepared by using palladium chloride (PdCl₂), copper sulfate (CuSO₄), ethylenediaminetetraacetic acid (EDTA), and formaldehyde (HCHO) in DI water.

Here, the pH of the electroless plating liquid is appropriately adjusted by using tetramethyl ammonium hydroxide (TMAH), to form a palladium-copper mixed thin film on the palladium plating layer 300.

Then, the palladium-copper mixture plating layer 400 is immersed in a gold galvanic electrolytic liquid, to replace a portion of copper particles (420) positioned above in the palladium-copper mixture with gold particles (510) by a replacement reaction, so that an upper portion of the palladium-copper mixture plating layer 400 is formed to be a first gold thin film 500 (S60).

The galvanic replacement reaction is a replacement process using a potential difference between metal ions, by which copper of the palladium-copper thin film is replaced with gold. For example, a galvanic electrolytic liquid is prepared from gold chloride (HAuCl₄) and perchloric acid (HClO₄), and is then used to proceed with a replacement reaction at room temperature, to thereby form a gold thin film.

FIG. 4 shows that copper particles are replaced with gold particles due to the galvanic replacement reaction. When the galvanic replacement reaction is performed on the palladium-copper mixture plating layer 400, which is formed of the palladium-copper mixture in which palladium particles 410 and copper particles 420 are dispersed, by using a potential difference between two metals; a portion of the palladium-copper mixture plating layer, in particular, a portion of copper particles 420 distributed in an upper portion of the palladium-copper mixture plating layer are replaced with gold particles 510 to form a first gold thin film 500 on the palladium-copper mixture plating layer 400. Here, adhesive properties of the first gold thin film 500 may be improved.

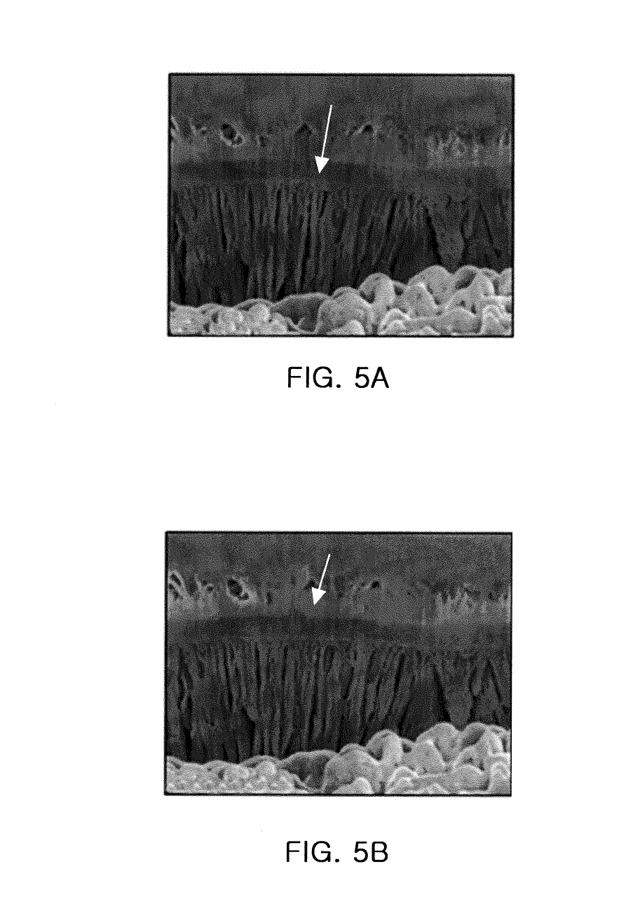

FIG. 5A is an FIB SEM image of the surface of the printed circuit board before the Galvanic Replacement Reaction, and FIG. 5B is an FIB SEM image of the surface of the printed circuit board after the Galvanic Replacement Reaction.

When components of the same portion indicated by arrows in FIGS. 5A and 5B were analyzed by energy dispersive X-ray spectroscopy (EDS), the component of the corresponding portion before the galvanic replacement reaction showed copper of 44.87 wt % and 60.47 at %, gold of 13.10 wt % and 5.69 at %, and palladium of 42.03 wt % and 33.83 at %, and the component of the corresponding portion after the galvanic replacement reaction showed copper of 9.65 wt % and 23.99 at %, gold 85.15 wt % and 68.29 at %, and palladium of 5.20 wt % and 7.72 at %. That is, it may be confirmed that after the galvanic replacement reaction, the upper portion of the palladium-copper mixture plating layer 400 was formed to be the first gold thin film 500.

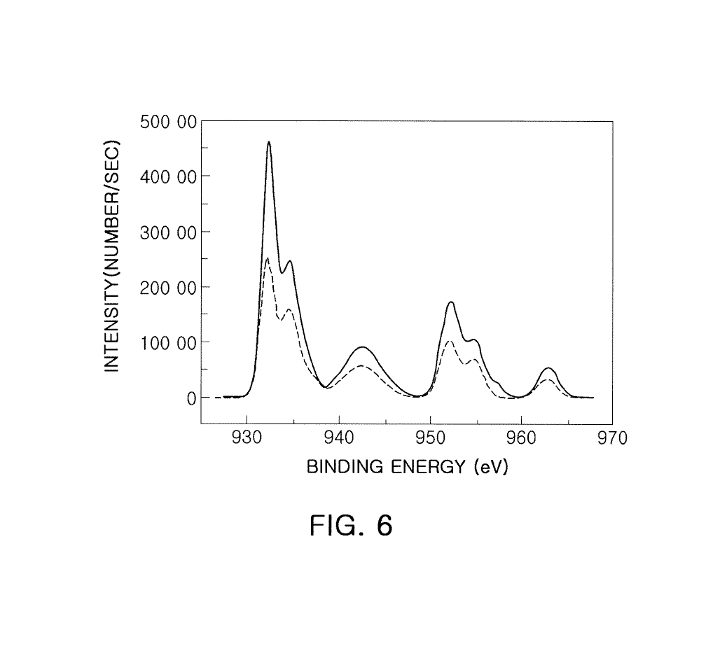

FIG. 6 is a graph showing X-ray photoelectron spectroscopy result of a surface of the printed circuit board according to an embodiment of the present invention. It can be confirmed that at the similar binding energy, the intensity of the palladium-copper mixture plating layer 400 is similar to that of the first gold thin film 500, and as the binding energy is increased to 930 eV or higher after the galvanic replacement reaction, the intensity of copper is reduced.

As described above, it can be confirmed that according to the results shown in FIG. 5A to FIG. 6, the upper portion of the palladium-copper mixture plating layer 400 is transformed into the first gold thin film 500.

Then, as necessary, a second gold thin film 600 with a predetermined thickness may be further formed on the first gold thin film 500 through electroless gold plating (S70).

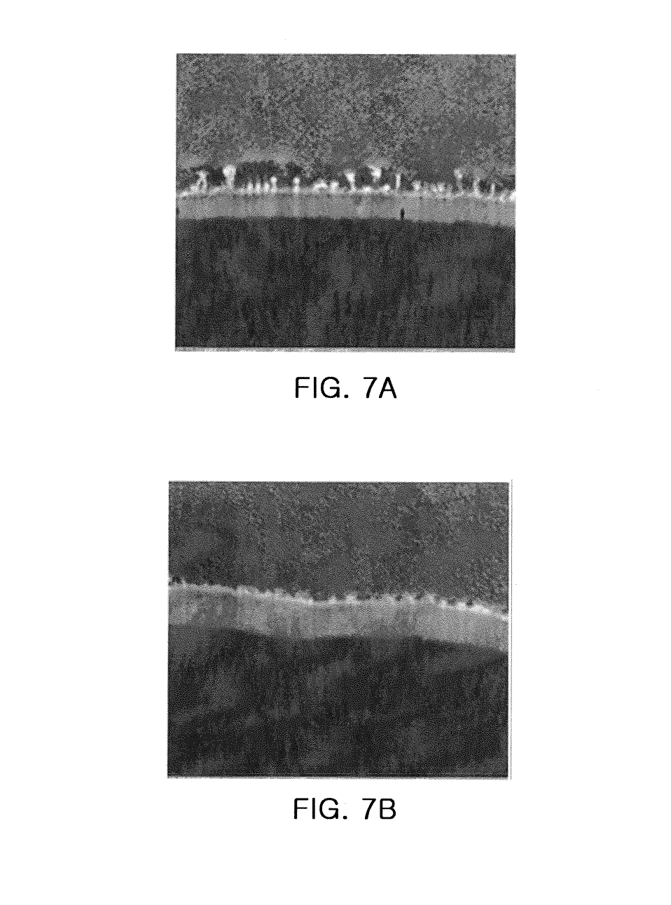

For example, FIG. 7A shows the first gold thin film 500 formed by the galvanic replacement reaction, and FIG. 7B shows the second gold thin film 600 with a predetermined thickness further formed on the first gold thin film 500 through a further electroless gold plating process. The second gold thin film 600 is for further securing the thickness of the gold thin film and reducing the roughness of the gold thin film.

Here, the electroless plating liquid therefor may be prepared from gold potassium cyanide (KAu(CN)₂), potassium cyanide (KCN), potassium hydroxide (KOH), and dimethylamine borane (DMAB), and may be then used to form a further thin film on the first gold thin film.

### Inventive Example 1

A printed circuit board was treated with an acid solution containing 9.8 g/L of sulfuric acid at room temperature for 1 minute, to remove a copper oxide film, and was then washed with distilled water and then dried with nitrogen gas.

The dried printed circuit board was catalyst-activated in a solution containing 1 g/L of tin chloride (SnCl₂) and 1 ml/L of hydrochloric acid (HCl) and a solution containing palladium chloride (PdCl₂) and 1 ml/L of hydrochloric acid at room temperature for 5 minutes, respectively.

Then, an electroless nickel plating liquid was prepared from 30 g/L of nickel chloride (NiCl₂), 10 g/L of sodium hypophosphite (NaH₂PO₂), 12.6 g/L of sodium citrate (Na₃C₆H₅O₇), and 5 g/L of sodium acetate (NaC₂H₃O₂), and was then used to proceed with electroless plating at 83° C., to thereby form the nickel plating layer 200 with a thickness of about 5 μm on the circuit pattern 100 of the printed circuit board.

Then, an electroless palladium plating liquid was prepared from 4 g/L of palladium chloride (PdCl₂), 300 ml/l of ammonia water (NH₄OH), 30 g/L of ethylenediaminetetraacetic acid (EDTA), 5 ml/L of hydrochloric acid (HCl), and 0.16 g/L of hydrazine (N₂H₄), and was then used to proceed with electroless plating at 73° C., to form a palladium plating layer 300 having a thickness of about 54 nm on the nickel plating layer 200.

Then, in order to perform palladium-copper mixture plating, an electrolytic liquid was prepared from 1.77 g/L of palladium chloride (PdCl₂), 1.25 g/L of copper sulfate (CuSO₄), ethylenediaminetetraacetic acid (EDTA), and 3 g/L of formaldehyde (HCHO).

Here, PH was adjusted to be a pH of 2 by using tetramethyl ammonium hydroxide (TMAH), and a plating furnace was maintained at 73° C., the palladium-copper mixture plating layer 400 having a thickness of about 36 nm was formed on the palladium plating layer 300, so that the total thickness of the palladium plating layer 300 and the palladium-copper mixture plating layer 400 was about 90 nm.

Then, for the galvanic replacement reaction, the palladium-copper mixture plating layer 400 was immersed in an electrolytic liquid prepared from 0.8 g/L of gold chloride HAuCl₄) and 10 g/L of perchloric acid (HClO₄) for 3 minutes, to replace a portion of copper particles with gold particles, so that an upper portion of the palladium-copper mixture plating layer 400 was formed into a first gold thin film 500 with a thickness of about 18 nm.

Then, electroless gold plating was performed by using an electroless gold plating liquid prepared from 5.8 g/L of gold potassium cyanide (KAu (CN)₂), 1.3 g/L of potassium cyanide (KCN), 45 g/L of potassium hydroxide (KOH), and 23.5 g/L of dimethylamine borane (DMAB) while a plating furnace was maintained at 80° C., so that a second gold thin film 600 having a thickness of about 18 nm was formed on the first gold thin film 500.

The printed circuit board surface-treated as above was used to conduct a bonding test.

Here, when the wire bonding test was conducted on a printed circuit board of which a gold thin film had a total thickness of about 36 nm by the galvanic replacement reaction and electroless gold plating, it can be confirmed that there was obtained a wire bonding stress value of up to 6_{gd}, and thus defects do not occur in performing wire bonding.

As set forth above, according to the embodiments of the present invention, the surface treatment for wire bonding of the printed circuit board was performed by using an electroless plating process and a galvanic replacement reaction, which are wet processes, and thus, the gold thin film may be formed to have a significantly thin thickness as compared with the existing printed circuit board, so that the amount of gold required may be reduced, whereby costs for the surface treatment of the printed circuit board may be reduced.

While the present invention has been shown and described in connection with the embodiments, it will be apparent to those skilled in the art that modifications and variations may be made without departing from the spirit and scope of the invention as defined by the appended claims.

What is claimed is:

1. A method of forming a gold thin film, the method comprising:
forming a nickel plating layer on a surface of an object through electroless nickel (Ni) plating;
forming a palladium-copper mixture plating layer on the nickel plating layer through electroless plating using a palladium-copper (Pd—Cu) mixture; and
forming a first gold thin film by immersing the palladium-copper mixture plating layer in a gold (Au) galvanic electrolytic liquid to replace a portion of copper (Cu) particles in the palladium-copper mixture plating layer with gold particles through a replacement reaction.

2. The method of claim 1, further comprising, before the forming of the palladium-copper mixture plating layer, forming a palladium plating layer on the nickel plating layer through electroless palladium (Pd) plating.

3. The method of claim 1, further comprising, after the forming of the first gold thin film, forming a second gold thin film on the first gold thin film through electroless gold (Au) plating.

4. The method of claim 1, wherein the palladium-copper mixture contains a palladium salt, a copper salt, a complexing agent, and a reducing agent.

5. The method of claim 4, wherein the palladium salt is one selected from the group consisting of palladium chloride, palladium sulfate, and dichlorotetraamine palladium.

6. The method of claim 4, wherein the copper salt is one selected from the group consisting of copper sulfate (CuSO₄) and copper chloride (CuCl₂).

7. The method of claim 4, wherein the reducing agent is one selected from the group consisting of formaldehyde, hydrazine, and dimethylamineborane.

8. A printed circuit board, comprising:
a substrate;
a copper circuit pattern formed on a surface of the substrate;
a nickel plating layer formed on the copper circuit pattern;
a palladium-copper mixture plating layer formed on the nickel plating layer; and
a first gold thin film formed on the palladium-copper mixture plating layer.

9. The printed circuit board of claim 8, wherein the nickel plating layer and the palladium-copper mixture plating layer include a palladium plating layer interposed therebetween.

10. The printed circuit board of claim 8, wherein the first gold thin film includes a second gold thin film formed thereon.

11. The printed circuit board of claim 8, wherein the palladium-copper mixture contains a palladium salt, a copper salt, a complexing agent, and a reducing agent.

12. The printed circuit board of claim 11, wherein the palladium salt is one selected from the group consisting of palladium chloride, palladium sulfate, and dichlorotetraamine palladium.

13. The printed circuit board of claim 11, wherein the copper salt is one selected from the group consisting of copper sulfate (CuSO₄) and copper chloride (CuCl₂).

14. The printed circuit board of claim 11, wherein the reducing agent is one selected from the group consisting of formaldehyde, hydrazine, and dimethylamineborane.
